(19) United States
(12) Patent Application Publication
(10) Pub. No.: US 2024/0097650 A1
(43) Pub. Date: Mar. 21, 2024

(54) TUNABLE FERROELECTRIC ACOUSTIC RESONATOR STRUCTURE

(71) Applicant: Qorvo US, Inc., Greensboro, NC (US)

(72) Inventors: Nadim Khlat, Cugnaux (FR); Milad Zolfagharloo Koohi, Longwood, FL (US)

(21) Appl. No.: 18/242,066

(22) Filed: Sep. 5, 2023

Related U.S. Application Data
(60) Provisional application No. 63/406,791, filed on Sep. 15, 2022.
(60) Provisional application No. 63/476,525, filed on Dec. 21, 2022.

(51) Int. Cl. H03H 9/24

(52) U.S. Cl. CPC H03H 9/24

(57) ABSTRACT

A ferroelectric acoustic resonator structure is provided. The tunable ferroelectric acoustic resonator structure includes a pair of ferroelectric acoustic resonator networks coupled in parallel between a signal input and a signal output. The ferroelectric acoustic resonator networks are tuned by a pair of pulse voltages to resonate in a desired series resonance frequency. However, the pair of pulse voltages can change an equivalent capacitance to therefore cause a parallel resonance frequency of the tunable ferroelectric acoustic resonator structure to shift. Herein, the pair of pulse voltages are determined to cause one of the ferroelectric acoustic resonator networks to increase the equivalent capacitance and to cause another one of the ferroelectric acoustic resonator networks to decrease the equivalent capacitance by an equal amount. As a result, it is possible to keep the overall equivalent capacitance, and therefore the parallel resonance frequency, of the tunable ferroelectric acoustic resonator structure unchanged.

### RELATED APPLICATIONS

This application claims the benefit of U.S. provisional patent application Ser. No. 63/406,791, filed on Sep. 15, 2022, and the benefit of U.S. provisional patent application Ser. No. 63/476,525, filed on Dec. 21, 2022, the disclosures of which are hereby incorporated herein by reference in their entireties.

### FIELD OF THE DISCLOSURE

The technology of the disclosure relates generally to a tunable ferroelectric acoustic resonator structure.

### BACKGROUND

Wireless devices have become increasingly common in current society. The prevalence of these wireless devices is driven in part by the many functions that are now enabled on such devices for supporting a variety of applications. In this regard, a wireless device may employ a variety of circuits and/or components (e.g., filters, transceivers, antennas, and so on) to support different numbers and/or types of applications.

Ferroelectric acoustic resonators, such as ferroelectric bulk acoustic resonators (FBAR), offer ultra-small sizes and can operate at frequencies up to tens of gigahertz. As such, ferroelectric resonators are widely used as miniaturized filters in many high-frequency devices, such as fifth generation (5G) and 5G new radio (5G-NR) communication and/or navigation devices. The operating frequency (a.k.a. series/parallel resonance frequency) of a ferroelectric acoustic resonator is typically determined by an inner structure (e.g., thickness and elastic properties) of the ferroelectric acoustic resonator. As such, it is desirable to electrically control the ferroelectric acoustic resonator to operate at a desired operating frequency without changing the inner structure of the ferroelectric acoustic resonator.

### SUMMARY

Aspects disclosed in the detailed description include a tunable ferroelectric acoustic resonator structure. The tunable ferroelectric acoustic resonator structure includes a pair of ferroelectric acoustic resonator networks coupled in parallel between a signal input and a signal output. Understandably, the ferroelectric acoustic resonator networks can be tuned by a pair of pulse voltages to resonate in a desired series resonance frequency. However, the pair of pulse voltages can change an equivalent capacitance to therefore cause a parallel resonance frequency of the tunable ferroelectric acoustic resonator structure to shift. In embodiments disclosed herein, the pair of pulse voltages are so determined to cause one of the ferroelectric acoustic resonator networks to increase the equivalent capacitance and to cause another one of the ferroelectric acoustic resonator networks to decrease the equivalent capacitance by an equal amount. As a result, it is possible to keep the overall equivalent capacitance, and therefore the parallel resonance frequency, of the tunable ferroelectric acoustic resonator structure unchanged while tuning the series resonance frequency of the tunable ferroelectric acoustic resonator structure.

In one aspect, a tunable ferroelectric acoustic resonator structure is provided. The tunable ferroelectric acoustic resonator structure includes a resonator network. The resonator network is configured to present an equivalent capacitance between a signal input and a signal output in a parallel resonance frequency. The resonator network includes a first ferroelectric acoustic resonator network. The first ferroelectric acoustic resonator network is configured to cause a first variation in the equivalent capacitance in response to receiving a first pulse voltage. The resonator network also includes a second ferroelectric acoustic resonator network. The second ferroelectric acoustic resonator network is configured to cause a second variation in the equivalent capacitance in response to receiving a second pulse voltage. The tunable ferroelectric acoustic resonator structure also includes a control circuit. The control circuit is configured to determine the first pulse voltage and the second pulse voltage such that the first variation cancels the second variation to thereby keep the equivalent capacitance unchanged. The control circuit is also configured to apply the determined first pulse voltage and the determined second pulse voltage to the first ferroelectric acoustic resonator network and the second ferroelectric acoustic resonator network, respectively.

In another aspect, a resonator network is provided. The resonator network is configured to resonate at a series resonance frequency to pass a signal from a signal input to a signal output and present an equivalent capacitance between the signal input and the signal output in a parallel resonance frequency. The resonator network includes a first ferroelectric acoustic resonator network. The first ferroelectric acoustic resonator network is configured to receive a first pulse voltage for tuning the first ferroelectric acoustic resonator network to the series resonance frequency. The first ferroelectric acoustic resonator network is also configured to cause a first variation in the equivalent capacitance in response to receiving the first pulse voltage. The resonator network also includes a second ferroelectric acoustic resonator network. The second ferroelectric acoustic resonator network is configured to receive a second pulse voltage for tuning the second ferroelectric acoustic resonator network to the series resonance frequency. The second ferroelectric acoustic resonator network is also configured to cause a second variation in the equivalent capacitance in response to receiving the second pulse voltage. The first pulse voltage and the second pulse voltage are determined to cause the first variation to cancel the second variation to thereby keep the equivalent capacitance unchanged.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure and, together with the description, serve to explain the principles of the disclosure.

FIG. 1A is a schematic diagram of an exemplary existing tunable ferroelectric acoustic resonator;

FIG. 1B is a graphic diagram providing an exemplary illustration as to how an equivalent capacitance of the existing tunable ferroelectric acoustic resonator in FIG. 1A may change when a series resonance frequency of the existing tunable ferroelectric acoustic resonator is tuned;

FIG. 2 is a schematic diagram of an exemplary tunable ferroelectric acoustic resonator structure configured according to an embodiment of the present disclosure to keep an equivalent capacitance of the tunable ferroelectric acoustic resonator structure unchanged while the tunable ferroelectric acoustic resonator structure is tuned to a series resonance frequency;

FIG. 3 is a graphic diagram providing an exemplary illustration as to how the tunable ferroelectric acoustic resonator structure of FIG. 2 can keep the equivalent capacitance unchanged while the series resonance frequency is tuned;

FIG. 4 is a schematic diagram of an exemplary tunable ferroelectric acoustic resonator structure configured according to another embodiment of the present disclosure; and

FIG. 5 is a schematic diagram of an exemplary user element wherein the tunable ferroelectric acoustic resonator structure of FIGS. 2 and 4 can be provided.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include a tunable ferroelectric acoustic resonator structure. The tunable ferroelectric acoustic resonator structure includes a pair of ferroelectric acoustic resonator networks coupled in parallel between a signal input and a signal output. Understandably, the ferroelectric acoustic resonator networks can be tuned by a pair of pulse voltages to resonate in a desired series resonance frequency. However, the pair of pulse voltages can change an equivalent capacitance to therefore cause a parallel resonance frequency of the tunable ferroelectric acoustic resonator structure to shift. In embodiments disclosed herein, the pair of pulse voltages are so determined to cause one of the ferroelectric acoustic resonator networks to increase the equivalent capacitance and to cause another one of the ferroelectric acoustic resonator networks to decrease the equivalent capacitance by an equal amount. As a result, it is possible to keep the overall equivalent capacitance, and therefore the parallel resonance frequency, of the tunable ferroelectric acoustic resonator structure unchanged while tuning the series resonance frequency of the tunable ferroelectric acoustic resonator structure.

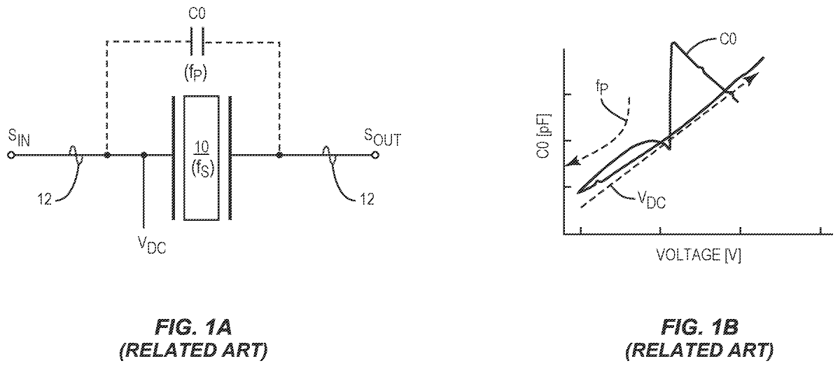

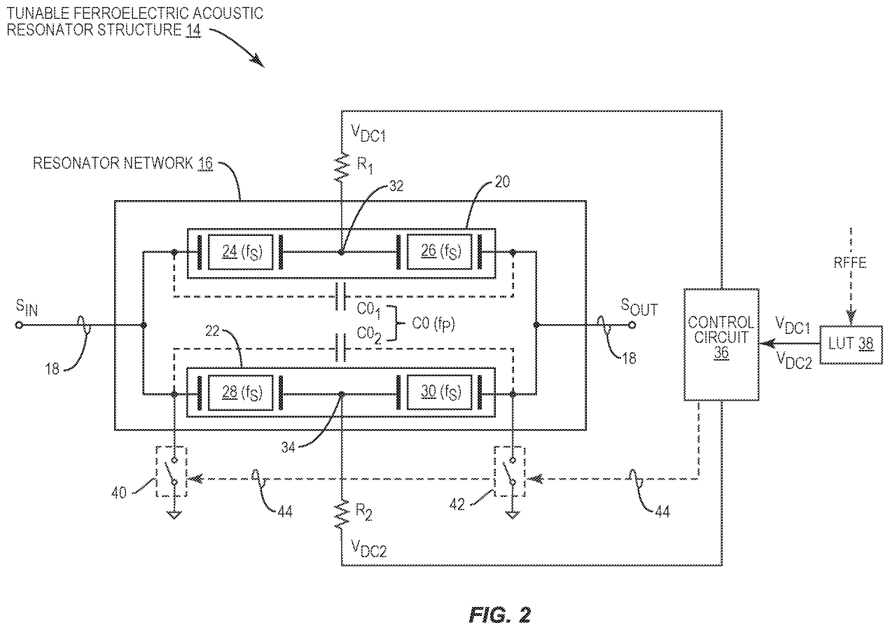

Before discussing a tunable ferroelectric acoustic resonator structure of the present disclosure, starting at FIG. 2, a brief discussion is first provided with reference to FIGS. 1A and 1B to help explain the technical problem to be solved by the tunable ferroelectric acoustic resonator structure of the present disclosure.

FIG. 1A is a schematic diagram of an exemplary existing tunable ferroelectric acoustic resonator 10. The existing tunable ferroelectric acoustic resonator 10 is designed to resonate in a series resonance frequency f_{S} to pass a signal 12 from a signal input S_{IN} to a signal output S_{OUT}. The existing tunable ferroelectric acoustic resonator 10 is also designed to present an equivalent parallel capacitance C0 between the signal input S_{IN} and the signal output S_{OUT} to thereby block the signal 12 in a parallel resonance frequency f_{P} (f_{P}≠f_{S}).

The series resonance frequency f_{S} can be tuned by a pulse voltage V_{DC} that polarizes the existing tunable ferroelectric acoustic resonator 10. In this regard, FIG. 1B is a graphic diagram providing an exemplary illustration as to how an equivalent capacitance C0 of the existing tunable ferroelectric acoustic resonator 10 in FIG. 1A may change when the series resonance frequency f_{S} of the existing tunable ferroelectric acoustic resonator 10 is tuned.

As shown in FIG. 1B, the pulse voltage V_{DC} can cause the equivalent capacitance C0 to increase. As a result, the parallel resonance frequency f_{P} will decrease. The decrease in the parallel resonance frequency f_{P} can create problems (e.g., insufficient separation between a passband and a stopband) in some applications. As such, it is desirable to keep the equivalent capacitance CO unchanged while tuning the series resonance frequency f_{S} of the existing tunable ferroelectric acoustic resonator 10.

In this regard, FIG. 2 is a schematic diagram of an exemplary tunable ferroelectric acoustic resonator structure 14 configured according to an embodiment of the present disclosure to keep an equivalent capacitance C0 of the tunable ferroelectric acoustic resonator structure 14 unchanged while the tunable ferroelectric acoustic resonator structure 14 is tuned to a series resonance frequency f_{S}. The tunable ferroelectric acoustic resonator structure 14 includes a resonator network 16. The resonator network 16 is coupled between a signal input S_{IN} and a signal output S_{OUT}. Like the existing tunable ferroelectric acoustic resonator 10, the resonator network 16 is configured to resonate in a series resonance frequency f_{S} to pass a signal 18 from the signal input S_{IN} to the signal output S_{OUT}. The resonator network 16 is also configured to present the equivalent capacitance C0 in a parallel resonance frequency f_{P} to block the signal 18 between the signal input S_{IN} and the signal output S_{OUT}.

According to an embodiment of the present disclosure, the resonator network 16 includes a first ferroelectric acoustic resonator network 20 and a second ferroelectric acoustic resonator network 22 that are coupled in parallel between the signal input S_{IN} and the signal output S_{OUT}. Specifically, the first ferroelectric acoustic resonator network 20 includes a pair of first ferroelectric acoustic resonators 24, 26 coupled in series between the signal input S_{IN} and the signal output S_{OUT}, and the second ferroelectric acoustic resonator network 22 includes a pair of second ferroelectric acoustic resonators 28, 30 coupled in series between the signal input S_{IN} and the signal output S_{OUT}. The first ferroelectric acoustic resonators 24, 26 can be tuned to resonate in the series resonance frequency f_{S} to pass the signal 18 from the signal input S_{IN} to the signal output S_{OUT} by applying a first pulse voltage V_{DC1} to a first intermediate node 32 located in between the first ferroelectric acoustic resonators 24, 26. Likewise, the second ferroelectric acoustic resonators 28, 30 can be tuned to resonate in the series resonance frequency f_{S} to pass the signal 18 from the signal input S_{IN} to the signal output S_{OUT} by applying a second pulse voltage V_{DC2} to a second intermediate node 34 located in between the second ferroelectric acoustic resonators 28, 30.

Herein, the first ferroelectric acoustic resonator network 20 is configured to present a first equivalent capacitance C0₁ between the signal input S_{IN} and the signal output S_{OUT}, and the second ferroelectric acoustic resonator network 22 is configured to present a second equivalent capacitance C0₂ between the signal input S_{IN} and the signal output S_{OUT}. Prior to applying the first pulse voltage V_{DC1} and the second pulse voltage V_{DC2} respectively to the first intermediate node 32 and the second intermediate node 34, the first equivalent capacitance C0₁ and the second equivalent capacitance C0₂ each contribute to a portion (e.g., ½) of the equivalent capacitance C0 (C0=C0₁+C0₂).

However, when the first pulse voltage V_{DC1} and the second pulse voltage V_{DC2} are applied to tune the series resonance frequency f_{S} of the first ferroelectric acoustic resonator network 20 and the second ferroelectric acoustic resonator network 22, the first equivalent capacitance C0₁ will increase by a first variation ΔC₁, and the second equivalent capacitance C0₂ will increase by a second variation ΔC₂. As a result, the equivalent capacitance C0 will increase by a sum of ΔC₁+ΔC₂. In this regard, to keep the equivalent capacitance C0 unchanged during tuning of the series resonance frequency f_{S}, it is necessary to make sure that the first variation ΔC₁ and the second variation ΔC₂ can cancel out each other.

In this regard, the tunable ferroelectric acoustic resonator structure 14 can be configured to include a control circuit 36, which can be a field-programmable gate array (FPGA) or an application-specific integrated circuit (ASIC), as an example. Herein, the control circuit 36 is configured to determine the first pulse voltage V_{DC1} and the second pulse voltage V_{DC2} such that the first variation ΔC₁ and the second variation ΔC₂ can cancel each other. In other words, the first variation ΔC₁ and the second variation ΔC₂ need to be so generated with an equal amount of each other but with different polarities (ΔC₁=−ΔC₂). In this regard, when the first equivalent capacitance C0₁ is increased by ΔC₁, the second equivalent capacitance C0₂ is decreased by ΔC₂. Alternatively, when the first equivalent capacitance C0₁ is decreased by ΔC₁, the second equivalent capacitance C0₂ is increased by ΔC₂. As a result, a sum of the first equivalent capacitance C0₁ and the second equivalent capacitance C0₂, which equals the equivalent capacitance C0, will remain unchanged.

In an embodiment, the relative change of the first equivalent capacitance C0₁ and the second equivalent capacitance C0₂ can be achieved by applying an appropriate combination of the first pulse voltage V_{DC1} and the second pulse voltage V_{DC2} to the first intermediate node 32 and the second intermediate node 34.

In one embodiment, the first ferroelectric acoustic resonators 24, 26 and the second ferroelectric acoustic resonators 28, 30 are configured to have an identical polarity. For example, the first ferroelectric acoustic resonators 24, 26 and the second ferroelectric acoustic resonators 28, 30 are all c-type resonators or are all f-type resonators. In this regard, the first pulse voltage V_{DC1} can be a positive pulse voltage +V_{DC1} to cause the first equivalent capacitance C0₁ to decrease by ΔC₁ and the second pulse voltage V_{DC2} can be a negative pulse voltage −V_{DC2} to cause the second equivalent capacitance C0₂ to increase by ΔC₂.

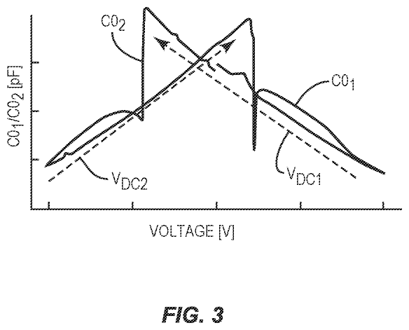

FIG. 3 is a graphic diagram providing an exemplary illustration as to how the tunable ferroelectric acoustic resonator structure 14 of FIG. 2 can keep the equivalent capacitance C0 unchanged while the series resonance frequency f_{S} is tuned. As shown in FIG. 3, when the negative pulse voltage −V_{DC2} increases, the second equivalent capacitance C0₂ increases accordingly. In contrast, when the positive pulse voltage V_{DC1} increases, the first equivalent capacitance C0₁ decreases accordingly. As such, the positive pulse voltage V_{DC1} and the negative pulse voltage −V_{DC2} can be so determined to cause the second equivalent capacitance C0₂ to increase by an equal amount as the first equivalent capacitance C0₁ decreases, thus keeping the equivalent capacitance C0 unchanged.

With reference back to FIG. 2, in an embodiment, the tunable ferroelectric acoustic resonator structure 14 can further include a predetermined lookup table (LUT) 38, which may be programmed (e.g., by a transceiver circuit) via a radio-frequency front-end (RFFE) interface. The control circuit 36 may retrieve a pair of the first pulse voltage V_{DC1} and the second pulse voltage V_{DC2} from the predetermined LUT 38. Understandably, each pair of the first pulse voltage V_{DC1} and the second pulse voltage V_{DC2} are predetermined to cause the first variation ΔC₁ and the second variation ΔC₂ to be generated with the equal amount of each other but with different polarities (ΔC₁=−ΔC₂). The control circuit 36 may retrieve the first pulse voltage V_{DC1} and the second pulse voltage V_{DC2} from the predetermined LUT 38 based on a range of parameters, such as the series resonance frequency f_{S} and/or the parallel resonance frequency f_{P}.

Upon determining the appropriate first pulse voltage V_{DC1} and the second pulse voltage V_{DC2} from the predetermined LUT 38, the control circuit 36 applies the first pulse voltage V_{DC1} and the second pulse voltage V_{DC2} to the first intermediate node 32 and the second intermediate node 34, respectively. In an embodiment, the control circuit 36 may be coupled to the first intermediate node 32 and the second intermediate node 34 via a first resistor R₁ and a second resistor R₂, respectively.

The tunable ferroelectric acoustic resonator structure 14 may also include a pair of switches 40, 42. Herein, the switch 40 is coupled to the signal input S_{IN} and the switch 42 is coupled to the signal output S_{OUT}. The switches 40, 42 may be opened or closed by the control circuit 36 via a control signal 44.

In an embodiment, the control circuit 36 may close the switches 40, 42 concurrent to applying the first pulse voltage V_{DC1} and the second pulse voltage V_{DC2} to the first ferroelectric acoustic resonator network 20 and the second ferroelectric acoustic resonator network 22, respectively. In contrast, the control circuit 36 may open the switches 40, 42 concurrent to removing the first pulse voltage V_{DC1} and the second pulse voltage V_{DC2} from the first ferroelectric acoustic resonator network 20 and the second ferroelectric acoustic resonator network 22, respectively.

In an alternative embodiment, the first ferroelectric acoustic resonators 24, 26 can have an opposite polarity to the second ferroelectric acoustic resonators 28, 30. For example, the first ferroelectric acoustic resonators 24, 26 are c-type resonators and the second ferroelectric acoustic resonators 28, 30 are f-type resonators, or vice versa. In this regard, the first pulse voltage V_{DC1} and the second pulse voltage V_{DC2} can each be a positive pulse voltage. Accordingly, the first variation ΔC₁ and the second variation ΔC₂ will have an identical amount of each other but opposite polarities to cancel out each other.

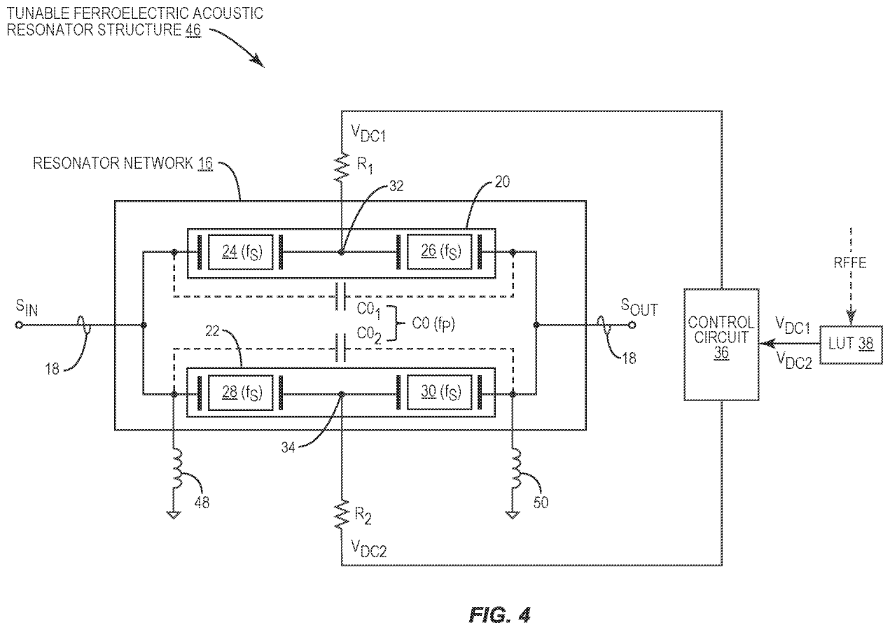

The switches 40, 42 in the tunable ferroelectric acoustic resonator structure 14 may be replaced by a pair of inductors. In this regard, FIG. 4 is a schematic diagram of an exemplary tunable ferroelectric acoustic resonator structure 46 configured according to another embodiment of the present disclosure. Common elements between FIGS. 2 and 4 are shown therein with common element numbers and will not be re-described herein.

Herein, the tunable ferroelectric acoustic resonator structure 46 includes a pair of shunt inductors 48, 50. The shunt inductor 48 is coupled to the signal input S_{IN} and the shunt inductor 50 is coupled to the signal output S_{OUT}. Each of the shunt inductors 48, 50 can act either as a high impedance or as a matching circuit at an RF frequency. The shunt inductors 48, 50 also allow a direct-current (DC) connection to ground for polarizing the resonator network 16 with the first pulse voltage V_{DC1} and the second pulse voltage V_{DC2}.

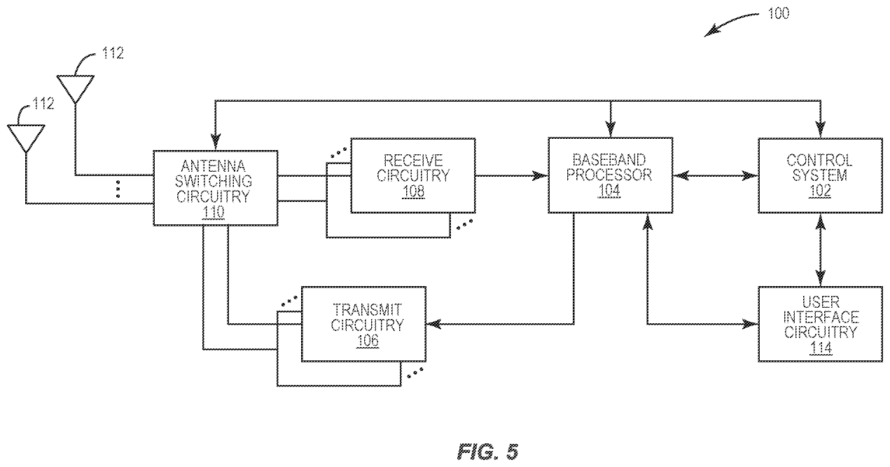

The tunable ferroelectric acoustic resonator structure 14 of FIG. 2 and the tunable ferroelectric acoustic resonator structure 46 of FIG. 4 can be provided in a user element to enable bandwidth adaptation according to embodiments described above. In this regard, FIG. 5 is a schematic diagram of an exemplary user element 100 wherein the tunable ferroelectric acoustic resonator structure 14 of FIG. 2 and the tunable ferroelectric acoustic resonator structure 46 of FIG. 4 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

Those skilled in the art will recognize improvements and modifications to the embodiments of the present disclosure. All such improvements and modifications are considered within the scope of the concepts disclosed herein and the claims that follow.

What is claimed is:

1. A tunable ferroelectric acoustic resonator structure comprising:
a resonator network configured to present an equivalent capacitance between a signal input and a signal output in a parallel resonance frequency, the resonator network comprising:
a first ferroelectric acoustic resonator network configured to cause a first variation in the equivalent capacitance in response to receiving a first pulse voltage; and
a second ferroelectric acoustic resonator network configured to cause a second variation in the equivalent capacitance in response to receiving a second pulse voltage; and
a control circuit configured to:
determine the first pulse voltage and the second pulse voltage such that the first variation cancels the second variation to thereby keep the equivalent capacitance unchanged; and
apply the determined first pulse voltage and the determined second pulse voltage to the first ferroelectric acoustic resonator network and the second ferroelectric acoustic resonator network, respectively.

2. The tunable ferroelectric acoustic resonator structure of claim 1, wherein the control circuit is further configured to determine the first pulse voltage and the second pulse voltage to cause the first variation and the second variation to have an equal amount but different polarities.

3. The tunable ferroelectric acoustic resonator structure of claim 1, wherein:
the first ferroelectric acoustic resonator network comprises a pair of first ferroelectric acoustic resonators coupled in series between the signal input and the signal output; and
the second ferroelectric acoustic resonator network comprises a pair of second ferroelectric acoustic resonators coupled in series between the signal input and the signal output.

4. The tunable ferroelectric acoustic resonator structure of claim 3, wherein the control circuit is further configured to:
apply the determined first pulse voltage to a first intermediate node located in between the pair of first ferroelectric acoustic resonators; and
apply the determined second pulse voltage to a second intermediate node located in between the pair of second ferroelectric acoustic resonators.

5. The tunable ferroelectric acoustic resonator structure of claim 4, wherein the control circuit is coupled to the first intermediate node and the second intermediate node via a first resistor and a second resistor, respectively.

6. The tunable ferroelectric acoustic resonator structure of claim 1, wherein:
the first ferroelectric acoustic resonator network and the second ferroelectric acoustic resonator network have an identical polarity; and
the control circuit is further configured to:
determine the first pulse voltage as a positive pulse voltage; and
determine the second pulse voltage as a negative pulse voltage.

7. The tunable ferroelectric acoustic resonator structure of claim 1, wherein:
the first ferroelectric acoustic resonator network and the second ferroelectric acoustic resonator network have opposite polarities; and
the control circuit is further configured to determine each of the first pulse voltage and the second pulse voltage as a positive pulse voltage.

8. The tunable ferroelectric acoustic resonator structure of claim 1, wherein the control circuit is further configured to apply the determined first pulse voltage and the determined second pulse voltage to the first ferroelectric acoustic resonator network and the second ferroelectric acoustic resonator network, respectively, to thereby cause each of the first ferroelectric acoustic resonator network and the second ferroelectric acoustic resonator network to resonate at a series resonance frequency to pass a signal from the signal input to the signal output.

9. The tunable ferroelectric acoustic resonator structure of claim 8, further comprising a predetermined lookup table (LUT) correlating the first pulse voltage and the second pulse voltage with the series resonance frequency.

10. The tunable ferroelectric acoustic resonator structure of claim 9, wherein the control circuit is further configured to determine the first pulse voltage and the second pulse voltage from the predetermined LUT based on the series resonance frequency.

11. The tunable ferroelectric acoustic resonator structure of claim 1, further comprising a pair of switches each coupled to a respective one of the signal input and the signal output, wherein the control circuit is further configured to:
close the pair of switches concurrent to applying the first pulse voltage and the second pulse voltage to the first ferroelectric acoustic resonator network and the second ferroelectric acoustic resonator network, respectively; and
open the pair of switches concurrent to removing the first pulse voltage and the second pulse voltage from the first ferroelectric acoustic resonator network and the second ferroelectric acoustic resonator network, respectively.

12. The tunable ferroelectric acoustic resonator structure of claim 1, further comprising a pair of shunt inductors each coupled to a respective one of the signal input and the signal output, wherein the pair of shunt inductors are configured to provide a direct-current (DC) connection to a ground for polarizing the resonator network with the first pulse voltage and the second pulse voltage.

13. A resonator network configured to resonate at a series resonance frequency to pass a signal from a signal input to a signal output and present an equivalent capacitance between the signal input and the signal output in a parallel resonance frequency, the resonator network comprising:
a first ferroelectric acoustic resonator network configured to:
receive a first pulse voltage for tuning the first ferroelectric acoustic resonator network to the series resonance frequency; and
cause a first variation in the equivalent capacitance in response to receiving the first pulse voltage; and
a second ferroelectric acoustic resonator network configured to:
receive a second pulse voltage for tuning the second ferroelectric acoustic resonator network to the series resonance frequency; and
cause a second variation in the equivalent capacitance in response to receiving the second pulse voltage;
wherein the first pulse voltage and the second pulse voltage are determined to cause the first variation to cancel the second variation to thereby keep the equivalent capacitance unchanged.

14. The resonator network of claim 13, wherein the first pulse voltage and the second pulse voltage are determined to cause the first variation and the second variation to have an equal amount but different polarities.

15. The resonator network of claim 13, wherein:
the first ferroelectric acoustic resonator network comprises a pair of first ferroelectric acoustic resonators coupled in series between the signal input and the signal output; and
the second ferroelectric acoustic resonator network comprises a pair of second ferroelectric acoustic resonators coupled in series between the signal input and the signal output.

16. The resonator network of claim 15, wherein:
the first ferroelectric acoustic resonator network is further configured to receive the first pulse voltage at a first intermediate node located in between the pair of first ferroelectric acoustic resonators; and
the second ferroelectric acoustic resonator network is further configured to receive the second pulse voltage at a second intermediate node located in between the pair of second ferroelectric acoustic resonators.

17. The resonator network of claim 13, wherein:
the first ferroelectric acoustic resonator network and the second ferroelectric acoustic resonator network have an identical polarity;
the first pulse voltage is a positive pulse voltage; and
the second pulse voltage is a negative pulse voltage.

18. The resonator network of claim 13, wherein:
the first ferroelectric acoustic resonator network and the second ferroelectric acoustic resonator network have opposite polarities; and
each of the first pulse voltage and the second pulse voltage is a positive pulse voltage.
